(19) United States
(12) Patent Application Publication
(10) Pub. No.: US 2026/0075754 A1
(43) Pub. Date: Mar. 12, 2026

(54) COOLING ASSEMBLY FOR PROCESSORS AND VOLTAGE REGULATORS

(71) Applicant: Super Micro Computer, Inc., San Jose, CA (US)

(72) Inventors: Cheng-Chuan CHIANG, New Taipei City (TW); Chia-Wei CHEN, New Taipei City (TW)

(21) Appl. No.: 18/883,363

(22) Filed: Sep. 12, 2024

(51) Int. Cl. H05K 7/20; G06F 1/16

(52) U.S. Cl. CPC H05K 7/20254; G06F 1/163; H05K 7/20263

(57) ABSTRACT

Disclosed is a cooling assembly for processors and voltage regulators. A processor is attached to a cold plate. A voltage regulator heatsink is removably attached to the cold plate. The voltage regulator heatsink has cooling fins and a heatsink base. The heatsink base is attached to a voltage regulator. Liquid coolant is flowed through the cold plate to cool the processor and the voltage regulator.

### TECHNICAL FIELD

The present disclosure is directed to cooling of electronic devices.

### BACKGROUND

Thermal management components are essential for maintaining the reliability and performance of electronic devices by effectively dissipating heat generated during operation. Examples of such thermal management components include cold plates, heatsinks, heat pipes, cooling fans, and other components designed to manage thermal loads.

For example, cold plates are commonly employed in direct liquid cooling systems to remove heat from high-performance processors, such as central processing units (CPUs), by circulating liquid coolant through channels that are in close proximity to the heat source. Similarly, heatsinks utilize extended surfaces, such as fins, to increase surface area and dissipate heat through natural or forced convection. In general, the appropriate selection and application of thermal management components help to prevent overheating, reduce the risk of thermal throttling, and prolong the lifespan of electronic devices.

### BRIEF SUMMARY

In one embodiment, a cooling assembly comprises a cold plate and a voltage regulator (VR) heatsink. The cold plate is attached to a processor, and comprises a plurality of ports that accept a liquid coolant. The VR heatsink is removably attached to the cold plate. The VR heatsink comprises a plurality of fins and a heatsink base that is attached to a heatsink mounting surface of a voltage regulator.

In another embodiment, a cooling system comprises a cold plate, a VR heatsink, and a pump. The cold plate is attached to a processor. The VR heatsink is removably attached to the cold plate. The VR heatsink comprises a plurality of fins and a heatsink base that is attached to a voltage regulator. The pump circulates a liquid coolant through the cold plate.

In yet another embodiment, a method of cooling a processor and a voltage regulator includes attaching a cold plate to the processor. A VR heatsink is removably attached to the cold plate, wherein the VR heatsink comprises a plurality of fins and a heatsink base. The heatsink base is attached to the voltage regulator. Liquid coolant is circulated through the cold plate.

These and other features of the present disclosure will be readily apparent to persons of ordinary skill in the art upon reading the entirety of this disclosure, which includes the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 shows an isometric view of a cooling assembly, in accordance with an embodiment of the present invention.

FIGS. 2 and 3 show a side view and a top view, respectively, of the cooling assembly of FIG. 1, in accordance with an embodiment of the present invention.

FIG. 4 shows a transparent top view of the cooling assembly of FIG. 1, in accordance with an embodiment of the present invention.

FIG. 5 shows a transparent side view of the cooling assembly of FIG. 1, in accordance with an embodiment of the present invention.

FIG. 6 shows a block diagram of a cooling system, in accordance with an embodiment of the present invention.

FIG. 7 shows an isometric view of a voltage regulator (VR) heatsink, in accordance with an embodiment of the present invention.

FIG. 8 shows a top view of the VR heatsink of FIG. 7, in accordance with an embodiment of the present invention.

FIG. 9 shows a side view of the VR heatsink of FIG. 7, in accordance with an embodiment of the present invention.

FIG. 10 shows another side view of the VR heatsink of FIG. 7, in accordance with an embodiment of the present invention.

### DETAILED DESCRIPTION

In the present disclosure, numerous specific details are provided, such as examples of materials, components, structures, and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

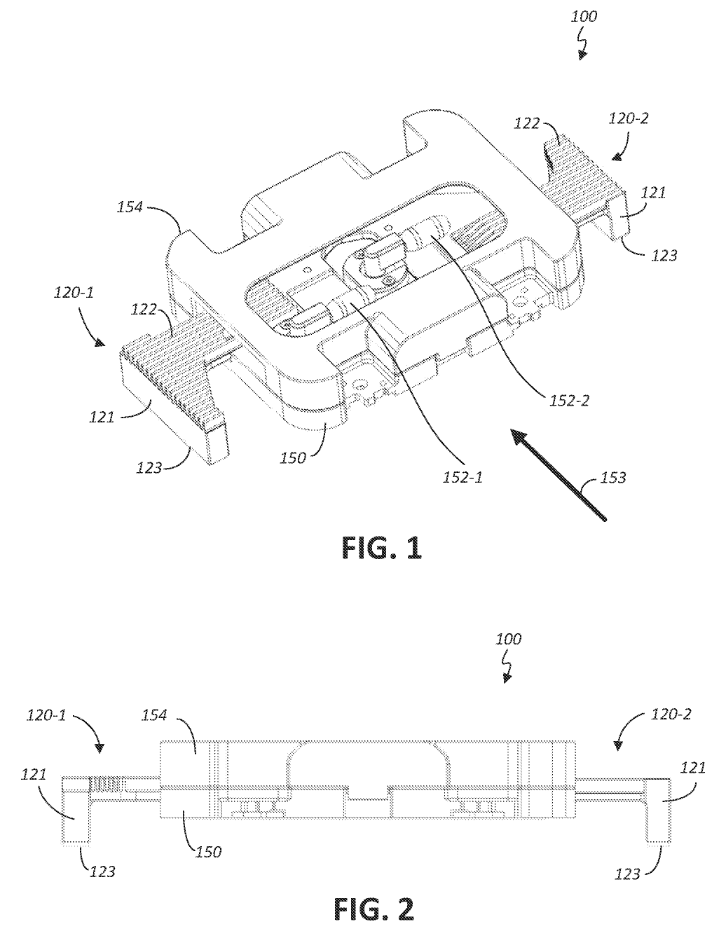

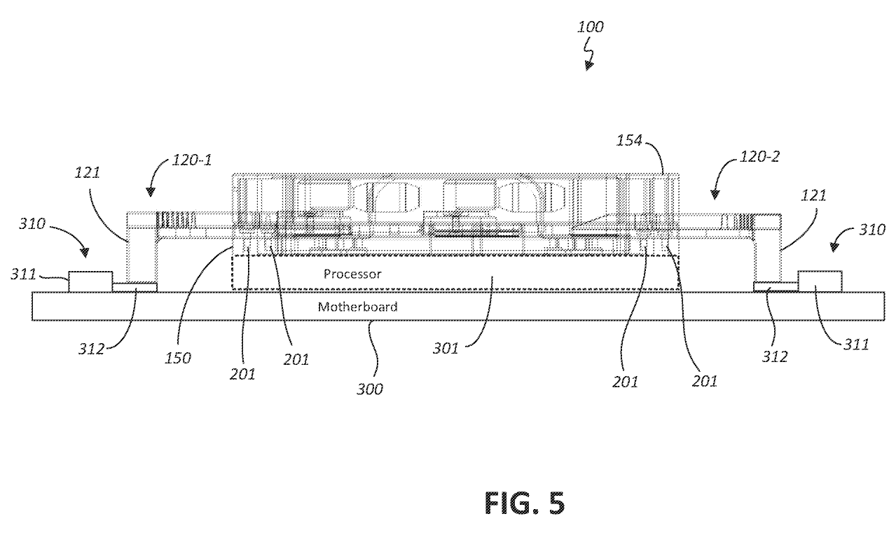

FIG. 1 shows an isometric view of a cooling assembly 100, in accordance with an embodiment of the present invention. In one embodiment, the cooling assembly 100 is configured to cool a processor and at least one voltage regulator, which are both shown in FIG. 5.

In the example of FIG. 1, the cooling assembly 100 includes a cold plate 150 and voltage regulator (VR) heatsinks 120 (i.e., 120-1, 120-2). The cold plate 150 includes liquid ports 152 (i.e., 152-1, 152-2) that are connected to plumbing (not shown) that circulates liquid coolant through the cold plate 150. In one embodiment, the port 152-2 is an inlet port and the port 152-1 is an outlet port. Liquid coolant enters through the port 152-2, flows through internal channels of the cold plate 150, and exits through the port 152-1. The cold plate 150 is attached to a processor, e.g., by way of a thermal interface material (TIM). Heat from the processor is transferred to the liquid coolant by way of the cold plate 150. A cover 154 is disposed to protect the top of the cold plate 150.

A VR heatsink 120 has cooling fins 122 and a heatsink base 121. The VR heatsink 120 is made of a high thermal conductivity material, such as aluminum or copper. The bottom surface 123 of the heatsink base 121 is attached to a voltage regulator, e.g., to a mounting tab of a power transistor (e.g., field-effect transistor (FET)) of the voltage regulator. The VR heatsink 120 may be soldered on and fastened (e.g., using screws) to the cold plate 150. The VR heatsink 120 is removable so that it can be readily replaced to accommodate different voltage regulators. The VR heatsink 120 allows heat from a voltage regulator to be transferred to the cold plate 150, and consequently to the liquid coolant.

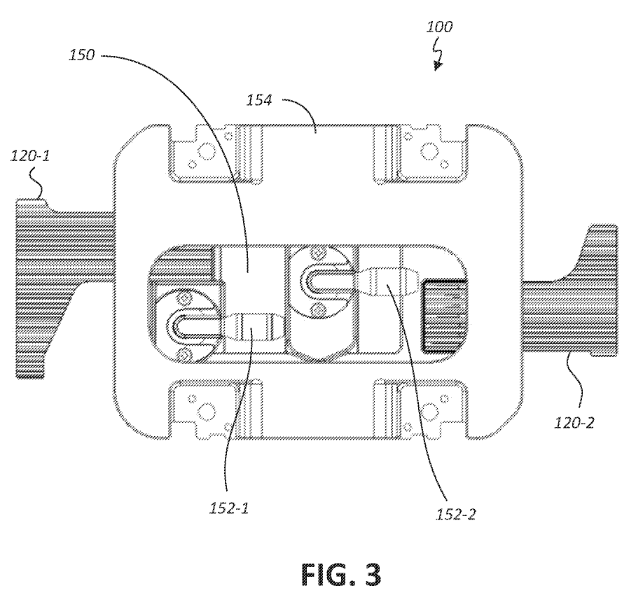

FIGS. 2 and 3 show a side view and a top view, respectively, of the cooling assembly 100, in accordance with an embodiment of the present invention. FIG. 2 is viewed in the direction of arrow 153 in FIG. 1.

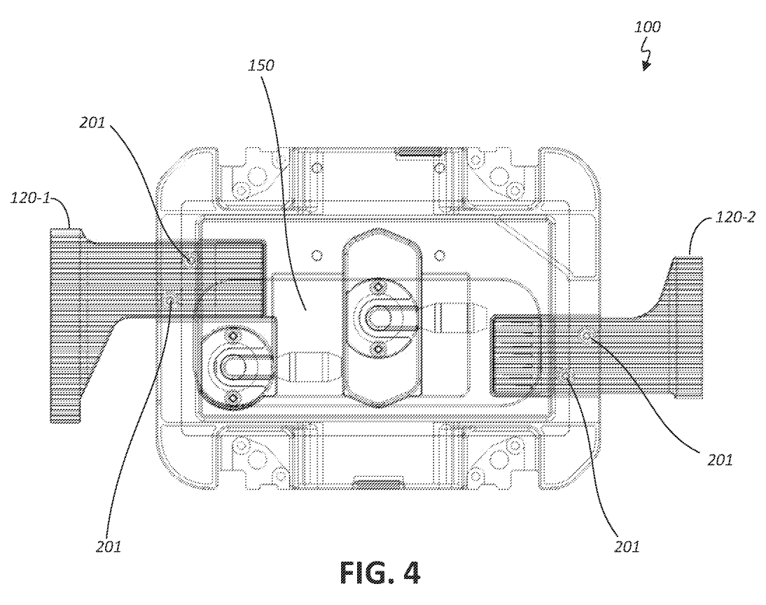

FIG. 4 shows a transparent top view of the cooling assembly 100, in accordance with an embodiment of the present invention. In one embodiment, the VR heatsinks 120 are removably attached to the cold plate 150 by fastening the VR heatsinks 120 to the cold plate 150 using screws 201 or other fastener.

FIG. 5 shows a transparent side view of the cooling assembly 100, in accordance with an embodiment of the present invention. FIG. 5 also shows schematic representations of a processor 301, substrate 300, and voltage regulators 310. FIG. 5 is viewed in the direction of arrow 153 in FIG. 1.

The processor 301 may be a CPU, graphics processing unit (GPU), application-specific integrated circuit (ASIC), neural processing unit (NPU), or other processor. In one embodiment, the substrate 300 is a printed circuit board (PCB) that serves as a motherboard of a server computer. The processor 301 and the voltage regulators 310 are mounted on the substrate 300. The cold plate 150 is attached to the processor 301, for example by way of a thermal interface material. The VR heatsinks 120 are fastened to the cold plate 150 by screws 201.

In the example of FIG. 5, a voltage regulator 310 includes an integrated circuit (IC) packaging 311 and a heatsink mounting surface 312. The packaging 311 may contain a power transistor, and the heatsink mounting surface 312 can be the mounting tab of the power transistor. The heatsink base 121 of the VR heatsink 120 may be attached to the heatsink mounting surface 312 by way of a thermal interface material, such as thermal grease. The thickness of the heatsink base 121 may be varied to accommodate the thickness of the heatsink mounting surface 312. The length of the VR heatsink 120 relative to the cold plate 150 in the horizontal direction may be varied to reach the corresponding heatsink mounting surface 312.

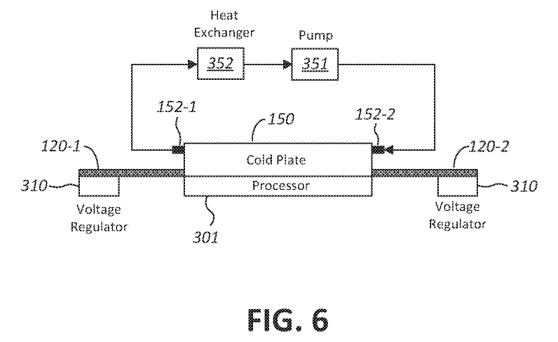

FIG. 6 shows a block diagram of a cooling system, in accordance with an embodiment of the present invention. The cooling system of FIG. 6 includes the cold plate 150, VR heatsinks 120, a pump 351, and a heat exchanger 352. Heat from the processor 301 is conducted to the cold plate 150. Heat from the voltage regulators 310 is conducted to the cold plate 150 via the VR heatsinks 120. Liquid coolant enters through the port 152-2, flows through the cold plate 150, and exits through the port 152-1. A pump 351 circulates the liquid coolant through the cold plate 150, and a heat exchanger 352 cools the heated liquid coolant exiting from the port 152-1.

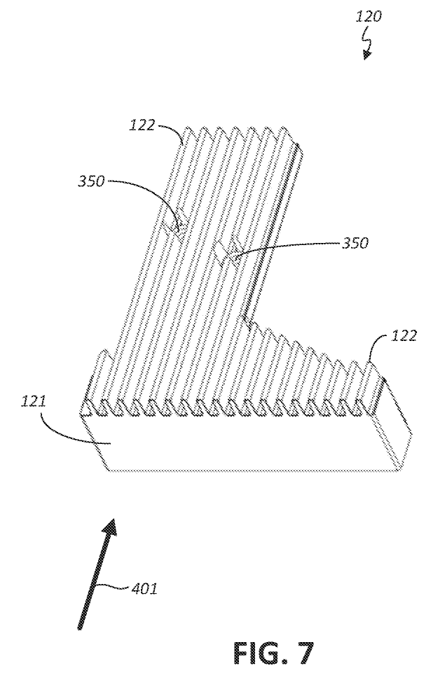

FIG. 7 shows an isometric view of the VR heatsink 120, in accordance with an embodiment of the present invention. In one embodiment, the VR heatsink 120 includes threaded holes 350 that accept screws 201 (shown in FIGS. 4 and 5) for removably attaching the VR heatsink 120 to the cold plate 150.

In one embodiment, the VR heatsink 120 has an L shape. This L shape allows the VR heatsink 120 to be efficiently connected to both the cold plate 150 and the voltage regulators 310. A first leg of the L shape that is attached to the cold plate 150 is in parallel with the tips of the fins 122, and a second leg of the L shape that is attached to the voltage regulator 310 is perpendicular with the tips of the fins 122.

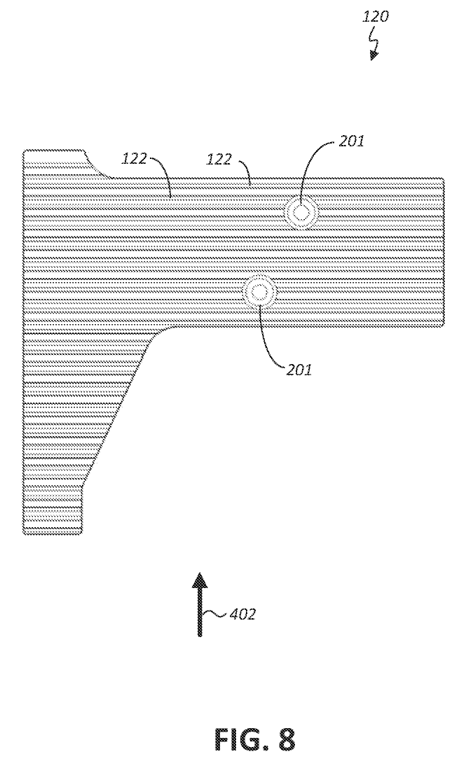

FIG. 8 shows a top view of the VR heatsink 120, in accordance with an embodiment of the present invention.

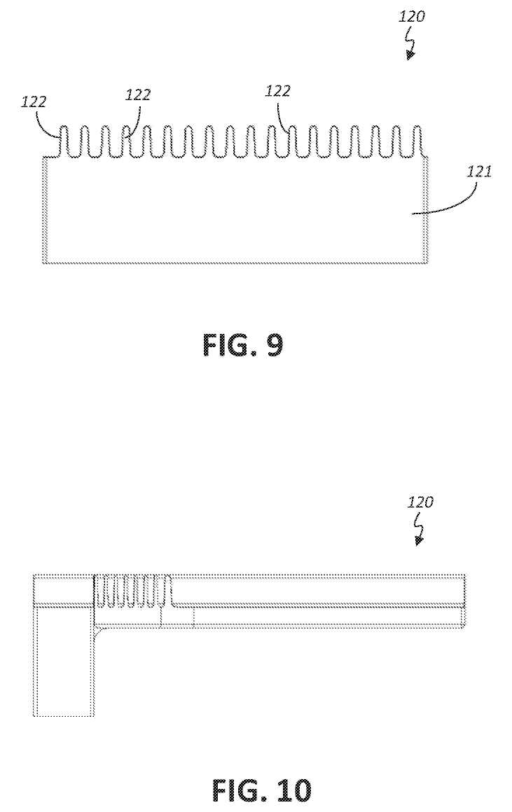

FIG. 9 shows a side view of the VR heatsink 120, in accordance with an embodiment of the present invention. FIG. 9 is viewed in the direction of arrow 401 in FIG. 7.

FIG. 10 shows another side view of the VR heatsink 120, in accordance with an embodiment of the present invention. FIG. 10 is viewed in the direction of arrow 402 in FIG. 8.

A cooling assembly for processors and voltage regulators has been disclosed. While specific embodiments of the present invention have been provided, it is to be understood that these embodiments are for illustration purposes and not limiting. Many additional embodiments will be apparent to persons of ordinary skill in the art reading this disclosure.

What is claimed is:

1. A cooling system comprising:
a cold plate that is attached to a processor;
a first voltage regulator (VR) heatsink that is removably attached to the cold plate, the first VR heatsink comprising a plurality of fins and a heatsink base that is attached to a first voltage regulator; and
a pump that circulates a liquid coolant through the cold plate.

2. The cooling system of claim 1, wherein the first VR heatsink has an L shape.

3. The cooling system of claim 1, further comprising:
a second VR heatsink that is removably attached to the cold plate, the second VR heatsink comprising a plurality of fins and a heatsink base that is attached to a second voltage regulator.

4. The cooling system of claim 1, wherein the first VR heatsink is fastened to the cold plate by a fastener.

5. The cooling system of claim 4, wherein the first VR heatsink is soldered on the cold plate.

6. The cooling system of claim 1, further comprising a heat exchanger that cools the liquid coolant.

7. The cooling system of claim 1, wherein the first voltage regulator comprises a power transistor, and the heatsink base of the first VR heatsink is attached to a heatsink mounting surface of the power transistor.

8. The cooling system of claim 1, wherein the processor is a central processing unit (CPU), and the CPU and the first voltage regulator are mounted on a motherboard.

9. A cooling assembly comprising:
a cold plate comprising a plurality of ports that accept a liquid coolant, the cold plate is attached to a processor; and
a first voltage regulator (VR) heatsink that is removably attached to the cold plate, the first VR heatsink comprising a plurality of fins and a heatsink base that is attached to a heatsink mounting surface of a first voltage regulator.

10. The cooling assembly of claim 9, wherein the heatsink mounting surface is a mounting tab of a power transistor of the voltage regulator.

11. The cooling assembly of claim 9, further comprising:
a second VR heatsink that is removably attached to the cold plate, the second VR heatsink comprising a plurality of fins and a heatsink base that is attached to a heatsink mounting surface of a second voltage regulator.

12. The cooling assembly of claim 9, further comprising a cover that is disposed on top of the cold plate.

13. The cooling assembly of claim 12, wherein the first VR heatsink is fastened and soldered to the cold plate.

14. A method of cooling a processor and a voltage regulator, the method comprising:
attaching a cold plate to the processor;
attaching a voltage regulator (VR) heatsink to the cold plate, the VR heatsink comprising a plurality of fins and a heatsink base;
attaching the heatsink base to the voltage regulator; and
circulating a liquid coolant through the cold plate.

15. The method of claim 14, further comprising:
attaching another VR heatsink to the cold plate, the other VR heatsink comprising a plurality of pins and a heatsink base; and
attaching the heatsink base of the other VR heatsink to another voltage regulator.
